(19) United States
(12) Patent Application Publication
(10) Pub. No.: US 2025/0079262 A1
(43) Pub. Date: Mar. 6, 2025

(54) METHODS AND APPARATUS FOR MULTI-ZONE TEMPERATURE CONTROL OF JET IMPINGEMENT COOLING OF INTEGRATED CIRCUIT PACKAGES

(71) Applicant: Intel Corporation, Santa Clara, CA (US)

(72) Inventors: Sami Mohammed Alelyani, Phoenix, AZ (US); Paul Jonathan Diglio, Gaston, OR (US); Gregorio Roberto Murtagian, Phoenix, AZ (US); Shengquan Ou, Chandler, AZ (US); Joseph Blane Petrini, Gilbert, AZ (US)

(73) Assignee: Intel Corporation, Santa Clara, CA (US)

(21) Appl. No.: 18/952,626

(22) Filed: Nov. 19, 2024

(51) Int. Cl. H01L 23/433; H01L 23/427

(52) U.S. Cl. CPC H01L 23/4336; H01L 23/427

(57) ABSTRACT

Systems, apparatus, articles of manufacture, and methods for temperature control of jet impingement cooling of integrated circuit packages are disclosed. An example system includes: a first nozzle to direct a first portion of impingement fluid towards an integrated circuit package; a second nozzle to direct a second portion of the impingement fluid towards the integrated circuit package; a first flow restrictor to control a first pressure of the first portion of the impingement fluid provided to the first nozzle; and a second flow restrictor to control a second pressure of the second portion of the impingement fluid provided to the second nozzle.

### BACKGROUND

Electronic components, such as microprocessors and integrated circuit packages, generally produce heat during operation. Excessive heat may degrade the performance, reliability, and/or life expectancy of such electronic components and may even cause component failure. Accordingly, in many instances, cooling systems are implemented to dissipate heat from such electronic components to maintain the operational temperature of such components within a suitable range. Some electronic components are cooled using heat dissipation/transfer through a fluid interfacing with the electronic component. Sometimes, the fluid directly contacts the electronic component to increase heat dissipation/transfer by eliminating an extra interfacing component.

### BRIEF DESCRIPTION OF THE DRAWINGS

FIG. 1 illustrates an example jet impingement cooling system constructed in accordance with teachings disclosed herein.

FIG. 2 illustrates another example jet impingement cooling system constructed in accordance with teachings disclosed herein.

FIG. 3 is a block diagram of an example implementation of the example controller circuitry of FIGS. 1 and/or 2.

FIG. 4 is a flowchart representative of example machine-readable instructions and/or example operations that may be executed, instantiated, and/or performed by example programmable circuitry to implement the controller circuitry of FIG. 3.

FIG. 5 is a block diagram of an example processing platform including programmable circuitry structured to execute, instantiate, and/or perform the example machine-readable instructions and/or perform the example operations of FIG. 4 to implement the controller circuitry of FIG. 3.

FIG. 6 is a block diagram of an example implementation of the programmable circuitry of FIG. 5.

FIG. 7 is a block diagram of another example implementation of the programmable circuitry of FIG. 5.

FIG. 8 is a block diagram of an example software/firmware/instructions distribution platform (e.g., one or more servers) to distribute software, instructions, and/or firmware (e.g., corresponding to the example machine-readable instructions of FIG. 4) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale.

### DETAILED DESCRIPTION

Integrated circuit (IC) packages (e.g., semiconductor chips) continue to get smaller over time, and with that, thermal densities (e.g., heat generated per measure of volume) of the IC packages increase to be able to maintain the same or better performance. To cool such IC packages, direct fluid cooling (e.g., cooling the electronic component by interfacing fluid/liquid directly with the electronic component) is one option to reduce (e.g., prevent) overheating, throttling, and/or damage. Further, direct fluid cooling can be used to control the temperature of IC packages (referred to herein as die temperature) for thermal testing.

One technique of direct fluid cooling is jet impingement cooling. Jet impingement cooling involves providing a liquid coolant (e.g., an impingement fluid) to one or more nozzles that produce a jet stream of the coolant that directly impinges on a surface of an IC package. In some instances, the IC package is water/fluid tight so that the coolant cannot reach the circuitry (e.g., transistors, interconnect, etc.) to avoid short circuits and/or other detrimental effects. Additionally or alternatively, gaskets or seals are positioned adjacent to the IC package so that the coolant only contacts portions of the IC package that are spaced apart from the circuitry. Additionally or alternatively, the coolant can be a dielectric coolant that come into direct contact with the circuits without causing a short circuit.

Some jet impingement cooling systems are single-phase systems in which the coolant remains in the same phase (e.g., the liquid phase) throughout the process. Other jet impingement cooling systems are two-phase systems in which at least some of the coolant changes between the liquid phase and the gas or vapor phase. Both single-phase and two-phase jet impingement cooling systems provide a significant localized cooling capacity (heat transfer coefficient) across an IC package. Frequently, the nozzles in jet impingement cooling systems are structured and located to target expected hotspots on an IC package. However, current implementations of jet impingement cooling systems are limited in the ability to quickly and dynamically control die temperature at certain locations (e.g., a given hotspot) on an IC package relative to other locations.

One approach to controlling or adjusting die temperatures at different locations on a given IC package cooled by a jet impingement cooling system is by mixing different temperatures of the coolant prior to providing the mixed coolant to the nozzles in the cooling system. In this manner, the inlet temperature of the coolant provided to any given nozzle can be controlled, thereby controlling the temperature at which the coolant impinges on the IC package to correspondingly control the die temperature of the package. Further, in some instances, by providing different mixtures of hot/warm and cold/cool coolant to different nozzles in the cooling system, the associated locations of the IC package can be cooled to different extents.

The are several disadvantages or limitations with mixing coolants at different input temperatures to control die temperature. First, controlling the inlet temperature of a coolant by mixing two or more different (e.g., hot and cold) sources of coolant necessitates multiple different valves for each different location of an IC package for which the die temperature is to be controlled. That is, for each location, region, or zone of an IC package that is to be temperature controlled, at least two valves are required (one for coolant at a first temperature (e.g., hot) and one for coolant at a second temperature (e.g., cold)) to produce the mixed coolant provided to the one or more nozzles associated with each location, region, or zone. Thus, if an IC package is divided into four zones, at least eight valves are needed. The need for so many valves drives up costs for such cooling systems and also introduces complexity in such systems. Furthermore, the relatively large number of valves increases the space needed in which to implement such a cooling system. Moreover, the increased space requirements can result in the valves being positioned farther away from the nozzles, which can negatively impact the response time of the system. Specifically, die temperature response time is a function of the location of the valves, and the thermal mass of the thermal head. Valves that are farther away from the nozzles are significantly slower in response time than valves that are closer to the nozzles. More particularly, experimental testing has shown that a valve located 1 meter away from the thermal head slows the die temperature response time by 600 milliseconds as compared to a valve positioned proximate to (e.g., within 20 centimeters of) the thermal head.

Another limitation of mixing coolants to control die temperature is the potential for cross-talk between different jet streams impinging on an IC package at different temperatures. After a jet stream from a nozzle initially hits an IC package, the jet stream disperses outward across the surface of the package. This outward dispersion of the coolant can extend towards and into other areas of the surface of the package that are directly impinged by another jet stream from another nozzle. If these two different nozzles are provided coolant at different inlet temperatures (due to different mixtures of the hot and cold coolant sources), then the dispersion of the coolant from the first nozzle (impinging at a first temperature) may disrupt the intended thermal operation of the coolant form the second nozzle (impinging at a second temperature).

Another limitation of mixing coolants to control die temperature is that it is not a viable approach for two-phase cooling. Indeed, there is currently no known way to control different zones of an IC package in a dynamic and independent manner using a two-phase jet impingement cooling system.

Examples disclosed herein overcome some or all of the limitations of mixing coolants to control die temperature. Specifically, as detailed below, rather than needing at least two valves for each independently controlled zone of an IC package, some examples disclosed herein use only a single valve for each zone. As a result, the cost and complexity of disclosed examples can be reduced relative to other approaches. Furthermore, the fewer number of components also enables disclosed examples to be implemented within a smaller space. Further still, while examples disclosed herein can be implemented in a smaller space with valves closer to the nozzles than previously known systems, the valves can be placed farther away from the nozzle than known coolant mixing systems without raising concerns for reduced response times because the response time of disclosed examples is decoupled from the fittings and the thermal head thermal mass. Indeed, experimental testing has shown that examples disclosed herein can achieve response times that are approximately 3 to 4 times faster than known coolant mixing systems. Thus, examples disclosed herein provide for much greater flexibility than known coolant mixing systems while also improving efficiency. Additionally, some examples disclosed herein reduce (e.g., eliminate) the concerns of cross-talk between different jet streams at different temperatures because the inlet temperature is substantially the same across the different nozzles used to provide the different jet streams. Further, examples disclosed herein can be implemented in conjunction with two-phase cooling systems.

Experimental findings indicate that the cooling capacity (e.g., the heat transfer coefficient) of a jet stream of coolant is linearly proportional to the jet velocity of the coolant at the outlet of an associated nozzle. Further, the jet velocity of the coolant out of a nozzle is linearly proportional to the inlet pressure of the coolant as provided to the associated nozzle. In other words, as the inlet pressure of the coolant increases, the jet velocity output by a nozzle increases, which results in an increase in the heat transfer coefficient of the coolant. Likewise, as the inlet pressure decreases, the jet velocity decreases, which results in a decrease in the heat transfer coefficient of the coolant. Thus, the die temperature for a given location of an IC package can be adjusted or controlled by adjusting the inlet pressure of a coolant provided to an associated nozzle that provides a jet stream impinging on the given location. Moreover, such temperature control can be implemented when the coolant temperature remains constant. As a result, the same coolant (at the same temperature) can be provided to a different nozzle at a different pressure to control the die temperature at a different associated location differently from the first location.

Dynamically controlling die temperature by adjusting the inlet pressure of coolant provided to nozzles as disclosed herein can reduce (e.g., minimize) capital costs because peak load typically does not occur simultaneously for all devices under test. Further, examples disclosed herein are not limited to thermal testing but can also be used to efficiently and reliably cool IC packages implemented by end users (e.g., enterprise hyperscale, datacenter, cloud service providers, etc.). More particularly, examples disclosed herein enable end users to boost up the thermal performance of an example cooling system during high load times (e.g., by modulating the inlet pressure) and lower thermal performance when the system is idle, thereby increasing energy efficiency. Furthermore, reliably controlling die temperature to specific set points with relatively rapid response times can reduce (e.g., minimize) package warpage and fatigue issues associated with thermomechanical cycling, thereby increasing package reliability.

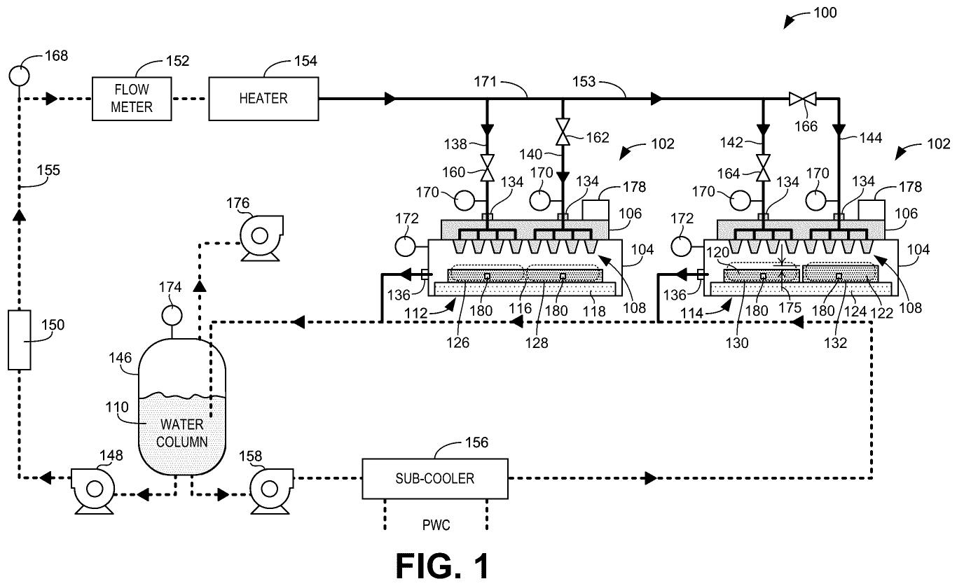

FIG. 1 illustrates an example jet impingement cooling system 100 constructed in accordance with teachings disclosed herein. The example cooling system 100 includes two thermal cooling assemblies 102. While two thermal cooling assemblies 102 are shown, in other examples, the jet impingement cooling system 100 includes only one thermal cooling assembly 102. In other examples, the jet impingement cooling system 100 includes more than two thermal cooling assembly 102.

As shown in the illustrated example, each thermal cooling assembly 102 includes a chamber 104 that is operatively coupled to an associated nozzle plate 106. In this example, each of the nozzle plates 106 includes and/or supports an associated array of nozzles 108. Although both nozzle plates 106 are shown as including eight nozzles, the array of nozzles 108 can include any suitable number of nozzles. Further, in some examples, the first array of nozzles 108 (associated with the first thermal cooling assembly 102) can include a different number of nozzles from the second array of nozzles 108 (associated with the second thermal cooling assembly 102). In the illustrated examples, the nozzles 108 are arranged to direct jet streams of a coolant 110 (e.g., an impingement fluid or coolant) towards corresponding IC packages (e.g., a first IC package 112 and a second IC package 114) within the respective chamber 104 of the respective thermal cooling assembly 102. In some examples, the thermal cooling assemblies 102 are constructed to implement thermal testing of IC packages 112, 114. In such examples, each IC package 112, 114 is sometimes generally referred to as a device under test (DUT). In other examples, the thermal cooling assemblies 102 are constructed to cool IC packages 112, 114 implemented for use by end users (e.g., enterprise hyperscale, datacenter, cloud service providers, etc.). In the illustrated example, the coolant 110 is water. However, in other examples, a different liquid coolant 110 may be employed. More particularly, in some examples, a dielectric coolant is used.

In the illustrated example of FIG. 1, the first IC package 112 includes a single semiconductor die 116 (e.g., chip, chiplet) mounted to a package substrate 118. By contrast, the second IC package 114 includes two separate semiconductor dies 120, 122 (e.g., chips, chiplets) mounted to a package substrate 124. In other examples, one or both of the IC packages 112, 114 can have a different number of semiconductor dies 116, 120, 122 from what is shown. In this example, the IC packages 112, 114 are bare-die packages in which the dies 116, 120, 122 are uncovered or exposed to direct impingement of the coolant 110 from the array of nozzles 108. However, in other examples, the dies 116, 120, 122 in one or both of the IC packages 112, 114 can be covered by a package lid (e.g., an integrated heat spreader).

In this example, the first IC package 112 includes two separate zones 126, 128 (demarcated by dashed lines) designated for independent temperature control. More particularly, the two zones 126, 128 of the first IC package 112 correspond to different portions of the single semiconductor die 116. The second IC package 114 of the illustrated example also includes two separate zones 130, 132 (demarcated by dashed lines) designated for independent temperature control. The two zones 130, 132 of the second IC package 114 correspond to respective ones of the two different semiconductor dies 120, 122. In other examples, a different number of zones and/or zones of different size and/or location can be designated for independent control in accordance with teachings disclosed herein. In this example, each of the zones is associated with (e.g., cooled by) four nozzles. However, in other examples, a different number of nozzles (e.g., 1, 2, 3, 5, 6, 7, 8, etc.) can be associated with each zone 126, 128, 130, 132. Further, in some examples, more nozzles may be associated with some zones than other zones.

As shown in the illustrated example, each thermal cooling assembly 102 includes a separate inlet port 134 that is fluidly coupled to the nozzles associated with each different zone 126, 128, 130, 132 of the IC packages 112, 114. Thus, in this example, each thermal cooling assembly 102 includes two inlet ports 134 corresponding to the two corresponding zones 126, 128, 130, 132 of the associated IC packages 112, 114. Further, in this example, each of the thermal cooling assemblies 102 includes an outlet port 136. Although only one outlet port 136 is shown, the thermal cooling assemblies 102 can include any number of outlet ports.

In some examples, the coolant 110 is provided to the different inlet ports 134 via separate inlet channels 138, 140, 142, 144 (e.g., fluid lines, tubes). The coolant 110 is directed from the inlet ports 134 though the nozzle plate 106 to the nozzles 108. The nozzles 108 produce jet streams of the coolant 110 that impinge on the IC packages 112, 114 before the coolant 110 is removed from the chamber 104 via the outlet port 136. In some examples, after leaving the chamber 104, the coolant 110 is returned to a tank 146 (e.g., a water column in the illustrated example) for reuse in the jet impingement cooling system 100.

More particularly, in some examples, a first pump 148 pumps the coolant 110 from the tank 146 towards the inlet channels 138, 140, 142, 144. In some examples, the coolant 110 is pumped through a filter 150 to remove particulates or other impurities that may affect the operation of the IC packages 112, 114. In some examples, the coolant 110 is also passed through a flow meter 152 to monitor the flow of the coolant 110. Further, in this example, the coolant 110 is passed through a heater 154 to heat up the coolant 110 before it is provided to the inlet channels 138, 140, 142, 144 leading back to the thermal cooling assemblies 102. For purposes of illustration, the flow path of the coolant 110 is represented by a thick solid line 153 when heated (e.g., after passing through the heater 154 until exiting the thermal cooling assemblies 102 at the outlet ports 136), whereas the coolant 110 is represented by a thick broken line 155 when cooled. As shown in the illustrated example, the coolant 110 is cooled after exiting the thermal cooling assemblies 102 because the coolant is combined with additional coolant 110 that has been pumped through a sub-cooler 156 by a second pump 158.

In the illustrated example, each of the inlet channels 138, 140, 142, 144 includes a corresponding adjustable flow restrictor 160, 162, 164, 166. As used herein, a flow restrictor includes any type of device capable of limiting or restricting the flow of fluid (e.g., the coolant 110) through a channel (e.g., the inlet channels 138, 140, 142, 144) so as to adjust (e.g., reduce) the pressure of the coolant 110 downstream of the flow restrictor. In some examples, the flow restrictors 160, 162, 164, 166 are implemented with any suitable type of valve (e.g., a proportional valve, a solenoid valve, a butterfly valve, a needle valve, etc.). In the illustrated example, the inlet channels 138, 140, 142, 144 are the only fluid lines carrying the coolant 110 towards the nozzles 108. Thus, in this example, the portion of the coolant 110 that is provided to any given nozzle necessarily passes through the corresponding inlet channel 138, 140, 142, 144 and, thus, the corresponding flow restrictor 160, 162, 164, 166. In other words, an entirety of the portion of the coolant provided to a given nozzle of the illustrated example flows through a corresponding one of the flow restrictors 160, 162, 164, 166.

As discussed above, adjusting the downstream pressure of the coolant 110 results in adjustment to the inlet pressure at the nozzles 108, which results in an adjustment (e.g., a proportional adjustment) to the jet velocity of the coolant 110 out of the nozzles. This adjustment to the jet velocity results in a (e.g., proportional) adjustment to the heat transfer coefficient of the coolant 110. Thus, adjustments to the flow restrictors 160, 162, 164, 166 can control the thermal cooling efficiency of the coolant 110 impinging on the IC packages 112, 114. More particularly, by independently controlling the different flow restrictors 160, 162, 164, 166, different die temperatures can be achieved for the different zones 126, 128, 130, 132. In this manner, it is possible to perform different tests at different temperatures in different zones at the same time (e.g., in parallel), thereby significantly reducing the overall thermal testing time for IC packages.

In some examples, the highest or maximum pressure of the coolant 110 that is provided to the nozzles 108 corresponds to when the flow restrictors 160, 162, 164, 166 are fully open. In such examples, the pressure is driven by the first pump 148 that pumps the coolant 110 through the jet impingement cooling system 100. In some examples, a first pressure sensor 168 (e.g., pressure gauge) is provided to measure this pressure along the fluid line that carries the coolant 110 towards the heater 154. In other examples, the first pressure sensor 168 can be at any other suitable location. Further, in some examples, additional pressure sensors 170 (e.g., pressure gauges) are positioned downstream of the flow restrictors 160, 162, 164, 166 to measure the inlet pressure of the coolant 110 provided to the nozzles 108. Relative to the known mixing approach that involves pumping two separate lines of coolant (one hot and one cold), the example jet impingement cooling system 100 of FIG. 1 includes only a single input fluid line 171. As a result, the example system requires a lower overall flow rate, which results in reduced system energy consumption. In some examples, chamber pressure sensors 172 are positioned to measure the pressure inside the chambers 104. Further, in some examples, a coolant tank pressure sensor 174 is provided to measure pressure within the tank 146. In some examples, one or more of the pressure sensors 168, 170, 172, 174 is omitted.

As shown in FIG. 1, the coolant 110 that passes through all four inlet channels 138, 140, 142, 144 comes from the same source (e.g., along the same fluid line 171) that is heated by the same heater 154. Thus, different portions of the coolant 110 provided in each of the inlet channels 138, 140, 142, 144 have a same temperature based on the coolant being provided from a common fluid line 171 upstream of the inlet channels 138, 140, 142, 144. As a result, the temperature of the coolant 110 provided to any of the nozzles 108 is substantially the same as the temperature of the coolant 110 provided to every other nozzle. Therefore, there is no concern of cross-talk between the different jet streams because the mixing of the jet streams will not change the temperature.

Another advantage of the example jet impingement cooling system 100 of FIG. 1 is the ability to place the flow restrictors 160, 162, 164, 166 at any suitable distance from the corresponding inlet port 134 of the thermal cooling assembly 102. Thus, despite the fact that the second and fourth flow restrictors 160, 166 are placed at different distances from the corresponding thermal cooling assembly 102 (both of which are farther than the first and third flow restrictors 160, 164), each flow restrictor 160, 162, 164, 166 can still adjust the pressure of the coolant 110 that is provided to the nozzles 108. Moreover, the distance of the flow restrictors 160, 162, 164, 166 from the nozzles 108 has a negligible effect on the die temperature response time (unlike known approaches of temperature control based on mixing different temperatures of coolant).

Not only can example jet impingement cooling systems such as the example system 100 of FIG. 1 be used to independently control the temperature of different zones of an IC package in a reliable and efficient manner, such example systems provide flexibility to adapt to other circumstances not previously possible using known cooling systems. For instance, in the example of FIG. 1, the two semiconductor dies 120, 122 in the second IC package 114 have different heights resulting in a die height difference 175 as may occur in 2.5D and/or 3D architectures (e.g., IC packages with high bandwidth memory (HBM) stacks). In the past, thermal testing of dies having different heights was not possible and dummy dies needed to be implemented to provide die-to-die matching heights. However, examples disclosed herein can accommodate different die heights associated with different zones (as in FIG. 1) by adjusting the inlet pressure of the coolant 110 to achieve a suitable jet velocity that corresponds with the distance of the die as a function of the die height. Thus, the example jet impingement cooling system 100 can streamline and reduce the cost of thermal testing of IC packages in a manner not previously realized.

In some examples, the jet impingement cooling system 100 is implemented as a two-phase cooling system. In some such examples, the pressure inside the chambers 104 is maintained at a sub-atmospheric condition so that the incoming coolant 110 (which is at an elevated temperature) will pass the vapor dome and hit two-phases. In some such examples, the sub-atmospheric pressure within the chambers 104 is achieved by a vacuum pump 176 located downstream of the chamber outlet ports 136. In other examples, the vacuum pump 176 is omitted.

In some examples, the jet impingement cooling system 100 includes example controller circuitry 178 (e.g., one or more microcontrollers) to control the operations of different aspects of the cooling system 100. More particularly, in the illustrated example of FIG. 1, each of the thermal cooling assemblies 102 includes separate controller circuitry 178. In other examples, the same controller circuitry 178 controls the operations of both thermal cooling assemblies 102. In some examples, the controller circuitry 178 is communicatively coupled to the corresponding flow restrictors 160, 162, 164, 166 to adjust the downstream pressure of the coolant 110 that is provided to the nozzles 108. Further, in some examples, the controller circuitry 178 is communicatively coupled to the pressure sensors 170, 172 that provide inputs to the controller circuitry 178 to facilitate determinations of how the flow restrictors 160, 162, 164, 166 are to be adjusted and/or controlled.

In some examples, the controller circuitry 178 determines when and how to adjust the flow restrictors 160, 162, 164, 166 based on temperature data obtained from one or more temperature sensors 180 (e.g., a digital temperature sensor (DTS)) monitoring the temperature of the IC packages 112, 114 in substantially real time. That is, in some examples, the controller circuitry 178 is communicatively coupled with the temperature sensors 180. In this example, at least one temperature sensor 180 is included in each zone 126, 128, 130, 132 of the IC packages 112, 114 to provide the die temperature specific to the corresponding zone. In some examples, multiple temperature sensors 180 are included in a given zone 126, 128, 130, 132. In some examples, as represented in the illustrated example, the temperature sensors 180 can be embedded within the IC packages 112, 114. Additionally or alternatively, the temperature sensors 180 can be on an exterior surface of the IC packages 112, 114. In some examples, the temperature sensors 180 are located near locations in or on the semiconductor dies 116, 120, 122 that are known (or expected) to produce relatively high amounts of heat (e.g., are locations associated with potential hotspots).

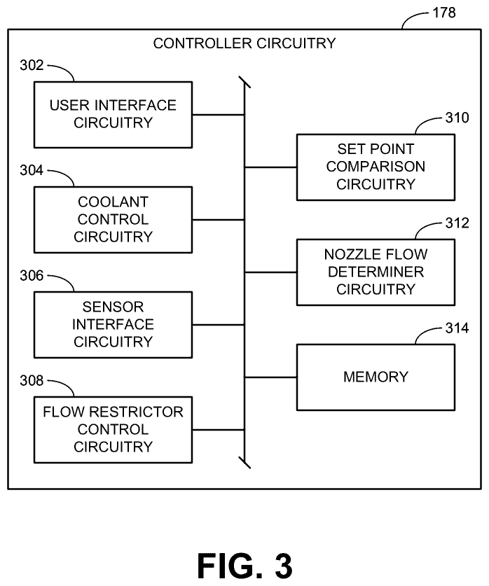

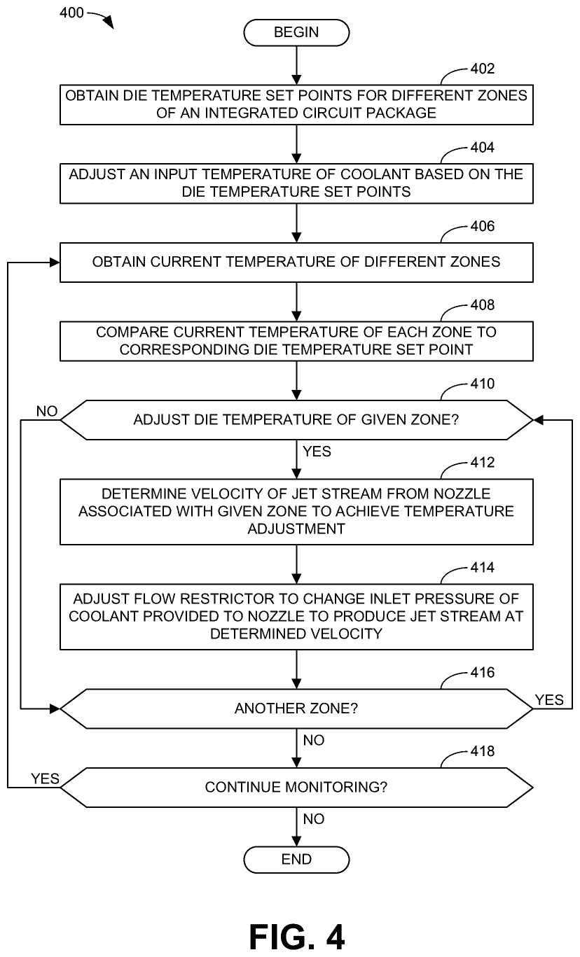

In some examples, the controller circuitry 178 is also communicatively coupled to the other components in the wider jet impingement cooling system 100 (e.g., one or more of the pumps 148, 158, 176, one or more of the other pressure sensors 168, 174, the filter 150, the flow meter 152, the heater 154, and/or the sub-cooler 156) to monitor and/or control the flow, movement, and/or temperature of the coolant 110 throughout the entire system 100. In some examples, controller circuitry separate from the circuitry that monitors and controls the flow restrictors 160, 162, 164, 166 monitors and controls these other components. Stated differently, in some examples, the controller circuitry 178 can be divided among different controllers implemented by distinct hardware at different locations. In other examples, some or all of the operations of the controller circuitry 178 can be implemented by a single piece of hardware. Thus, while FIG. 1 uses two blocks to illustrate the controller circuitry 178 coupled to the respective exteriors of the two thermal cooling assemblies 102, the controller circuitry 178 can be at any other suitable location(s) and can be combined into one block and/or distributed across three or more blocks at different locations (e.g., different than the locations shown). Further details regarding the implementation of the example controller circuitry 178 are provided below in connection with FIGS. 3 and 4.

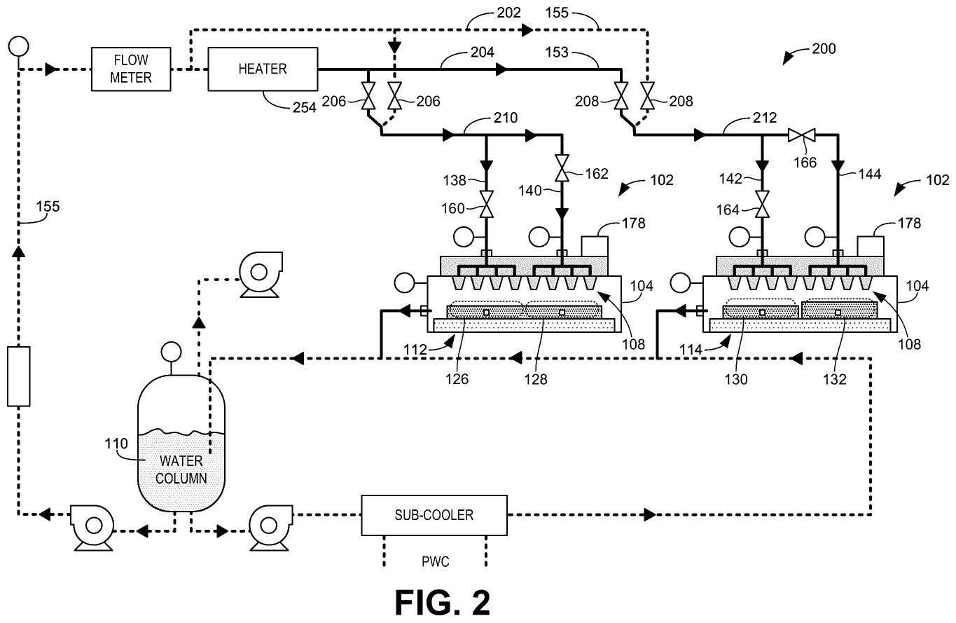

FIG. 2 illustrates another example jet impingement cooling system 200 constructed in accordance with teachings disclosed herein. The example jet impingement cooling system 200 of FIG. 2 is substantially the same as the example jet impingement cooling system 100 of FIG. 1 except as noted below and/or otherwise made clear from the context. Accordingly, the features shown in FIG. 2 that are the same or similar to corresponding features in FIG. 1 are identified by the same reference numbers. Further, the description of such features described above in connection with FIG. 1 applies similarly with respect to the corresponding features in FIG. 2.

The example of FIG. 2 differs from the example of FIG. 1 in that the example of jet impingement cooling system 200 of FIG. 2 enables independent control of the temperature of the coolant 110 provided to each of the thermal cooling assemblies 102. As discussed above in connection with FIG. 1, the coolant 110 is provided at a constant temperature to each of the different inlet channels 138, 140, 142, 144. As a result, the temperature of the coolant 110 provided to each of the nozzles 108 is substantially the same. An advantage of this implementation is the elimination of cross-talk between different jet streams impinging on the IC packages 112, 114 at different temperatures. However, this is only a concern for jet streams within the same chamber 104 of the same thermal cooling assembly 102. Accordingly, in the illustrated example of FIG. 2, the coolant temperature provided to each thermal cooling assembly 102 can be independently controlled.

More particularly, as shown in FIG. 2, the example jet impingement cooling system 200 includes a cold coolant line 202 and a heated coolant line 204 that can be mixed in any suitable manner via first and second mixing valves 206, 208. In this example, the first mixing valves 206 feed into a first fluid line 210 that is a common fluid line to both the first and second inlet channels 138, 140 associated with the first thermal cooling assembly 102, and the second mixing valves 208 feed into a second fluid line 212 that is a common fluid line to both the third and fourth inlet channels 142, 144 associated with the second thermal cooling assembly 102. As such, while the temperature of the first and second fluid lines 210, 212 may be different (and independently controlled), the same temperature is provided to each of the nozzles 108 in a given one of the thermal cooling assemblies 102. In some examples, the mixing valves 206, 208 are communicatively coupled to and controlled by the controller circuitry 178. In this way, greater flexibility in running thermal tests can be implemented by setting a different baseline temperature of the coolant 110 that is provided to each thermal cooling assembly 102. The die temperature of the different zones 126, 128, 130, 132 can still be independently controlled by adjusting the corresponding flow restrictor 160, 162, 164, 166 associated with each zone. Specifically, as discussed above, adjusting the flow restrictors 160, 162, 164, 166 changes the inlet pressure of the coolant 110 provided to the nozzles, which proportionally changes the jet velocity out of the nozzles, which affects the heat transfer coefficient of the coolant impinging on the respective zones 126, 128, 130, 132 of the IC packages 112, 114.

FIG. 3 is a block diagram of an example implementation of the controller circuitry 178 of FIGS. 1 and/or 2 to dynamically and independently control the die temperature of different zones in an IC package. The controller circuitry 178 of FIG. 3 may be instantiated (e.g., creating an instance of, bring into being for any length of time, materialize, implement, etc.) by programmable circuitry such as a Central Processor Unit (CPU) executing first instructions. Additionally or alternatively, the controller circuitry 178 of FIG. 3 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 3 may, thus, be instantiated at the same or different times. Some or all of the circuitry of FIG. 3 may be instantiated, for example, in one or more threads executing concurrently on hardware and/or in series on hardware. Moreover, in some examples, some or all of the circuitry of FIG. 3 may be implemented by microprocessor circuitry executing instructions and/or FPGA circuitry performing operations to implement one or more virtual machines and/or containers.

As shown in the illustrated example of FIG. 3, the controller circuitry 178 includes example user interface circuitry 302, example coolant control circuitry 304, example sensor interface circuitry 306, example flow restrictor control circuitry 308, example set point comparison circuitry 310, example nozzle flow determiner circuitry 312, and example memory 314.

The example controller circuitry 178 is provided with the example user interface circuitry 302 to enable a user to provide inputs to the controller circuitry 178 defining parameters for the operation of the example jet impingement cooling system 100, 200. For instance, in some examples, a user may provide, via the user interface circuitry 302, a coolant temperature set point to which the coolant 110 is to be heated by the heater 154. Additionally or alternatively, in some examples, a user may provide, via the user interface circuitry 302, multiple coolant temperature set points for each thermal cooling assembly 102 to which the coolant 110 is to be provided. In some such examples, the temperature set points define the temperature to which the coolant 110 is to be mixed using the mixing valves 206 of FIG. 2 associated with each thermal cooling assembly 102. Further, in some examples, a user may provide, via the user interface circuitry 302, different die temperature set points to which different zones of IC packages are to be controlled. In some examples, the coolant temperature set point(s) are defined by and/or determined based on the die temperature set points.

Additionally, in some examples, a user may provide, via the user interface circuitry 302, a baseline pressure or flow rate of the coolant 110 that is to be pumped through the example jet impingement cooling system 100, 200. In some examples, system parameters and/or other inputs received from a user through the user interface circuitry 302 are stored in the example memory 314. In some examples, the user interface circuitry 302 also enables information about the operation of the jet impingement cooling system 100, 200 to be output to a user. In some examples, the user interface circuitry 302 is instantiated by programmable circuitry executing user interface instructions and/or configured to perform operations such as those represented by the flowchart of FIG. 4.

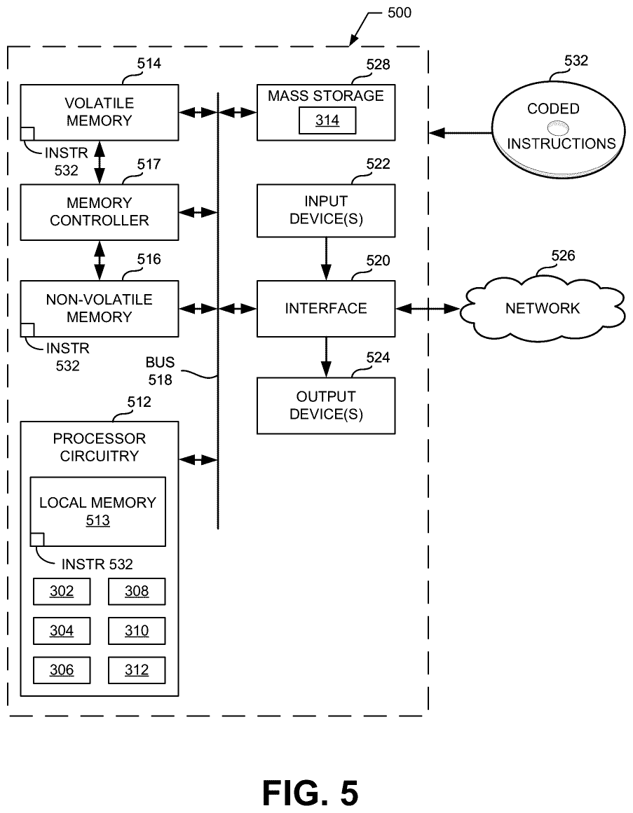

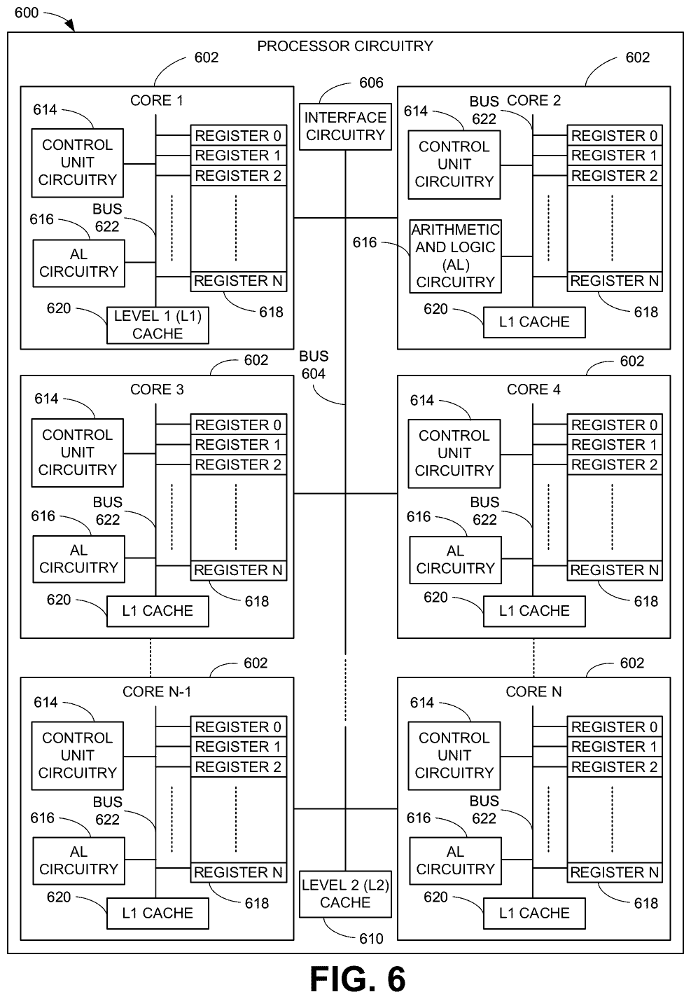

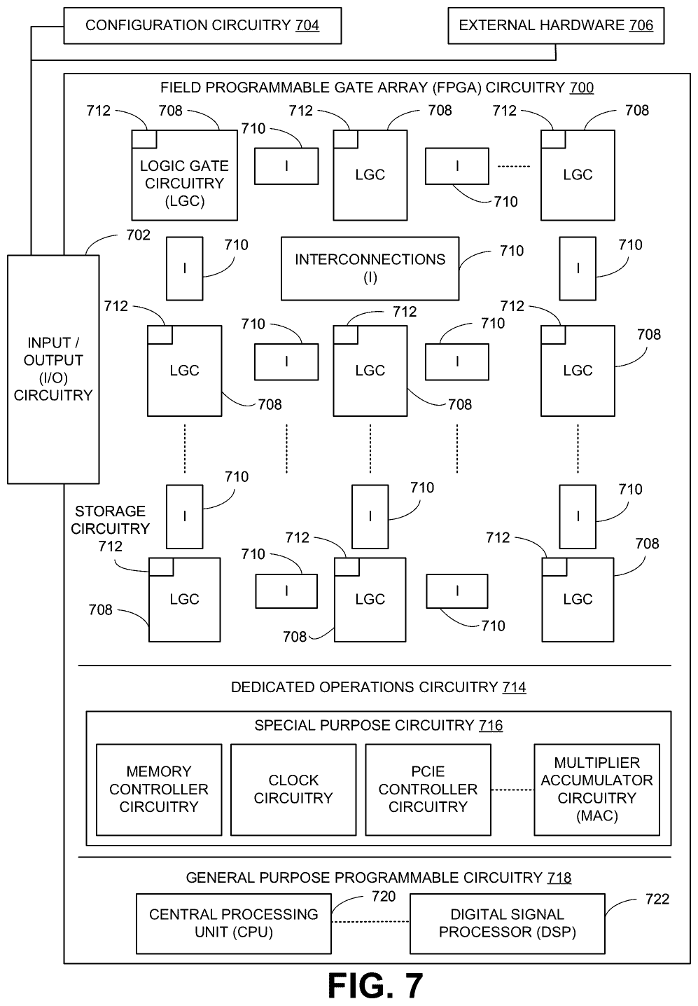

In some examples, the controller circuitry 178 includes means for obtaining set point values (e.g., die temperature set points, coolant input temperature set point, etc.). For example, the means for obtaining may be implemented by user interface circuitry 302. In some examples, the user interface circuitry 302 may be instantiated by programmable circuitry such as the example programmable circuitry 512 of FIG. 5. For instance, the user interface circuitry 302 may be instantiated by the example microprocessor 600 of FIG. 6 executing machine executable instructions such as those implemented by at least blocks 402 of FIG. 4. In some examples, the user interface circuitry 302 may be instantiated by hardware logic circuitry, which may be implemented by an ASIC, XPU, or the FPGA circuitry 700 of FIG. 7 configured and/or structured to perform operations corresponding to the machine-readable instructions. Additionally or alternatively, the user interface circuitry 302 may be instantiated by any other combination of hardware, software, and/or firmware. For example, the user interface circuitry 302 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

The example controller circuitry 178 is provided with the example coolant control circuitry 304 to control the flow rate and/or temperature of the coolant 110 that is circulated through the jet impingement cooling system 100, 200. That is, in some examples, the coolant control circuitry 304 generates and/or provides command signals that control operation of one or more of the pumps 148, 158, 176 to adjust and/or control the flow rate of the coolant 110 and/or the associated maximum pressure of the coolant. Additionally or alternatively, in some examples, the coolant control circuitry 304 generates and/or provides command signals that control operation of the heater 154 to adjust and/or control the temperature of the heated coolant 110. Further, in some examples, the coolant control circuitry 304 generates and/or provides command signals that control operation of the mixing valves 206 (FIG. 2) to adjust and/or control the temperature of the coolant 110 provided to a given thermal cooling assembly 102. In some examples, the coolant control circuitry 304 is instantiated by programmable circuitry executing coolant control instructions and/or configured to perform operations such as those represented by the flowchart of FIG. 4.

In some examples, the controller circuitry 178 includes means for adjusting characteristics of a coolant (e.g., means for adjusting an input temperature of the coolant, means for adjusting a flow rate of the coolant, etc.). For example, the means for adjusting may be implemented by coolant control circuitry 304. In some examples, the coolant control circuitry 304 may be instantiated by programmable circuitry such as the example programmable circuitry 512 of FIG. 5. For instance, the coolant control circuitry 304 may be instantiated by the example microprocessor 600 of FIG. 6 executing machine executable instructions such as those implemented by at least block 404 of FIG. 4. In some examples, the coolant control circuitry 304 may be instantiated by hardware logic circuitry, which may be implemented by an ASIC, XPU, or the FPGA circuitry 700 of FIG. 7 configured and/or structured to perform operations corresponding to the machine-readable instructions. Additionally or alternatively, the coolant control circuitry 304 may be instantiated by any other combination of hardware, software, and/or firmware. For example, the coolant control circuitry 304 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

The example controller circuitry 178 is provided with the example sensor interface circuitry 306 to communicate with and receive sensor data from one or more of the sensors implemented in the example jet impingement cooling system 100, 200. For instance, in some examples, the sensor interface circuitry 306 receives pressure data from one or more of the pressure sensors 168, 170, 172, 174. Additionally or alternatively, in some examples, the sensor interface circuitry 306 receives temperature data from one or more of the temperature sensors 180. Further, in some examples, the sensor interface circuitry 306 receives flow data from the flow meter 152 and/or additional sensor data from sensors associated with the pumps 148, 158, 176, the filter 150, and/or the heater 154. In some examples, the sensor interface circuitry 306 is instantiated by programmable circuitry executing sensor interface instructions and/or configured to perform operations such as those represented by the flowchart of FIG. 4.

In some examples, the controller circuitry 178 includes means for obtaining sensor data (e.g., means for obtaining temperature data (e.g., current (measured) temperature), means for obtaining pressure data, etc.). For example, the means for obtaining may be implemented by sensor interface circuitry 306. In some examples, the sensor interface circuitry 306 may be instantiated by programmable circuitry such as the example programmable circuitry 512 of FIG. 5. For instance, the sensor interface circuitry 306 may be instantiated by the example microprocessor 600 of FIG. 6 executing machine executable instructions such as those implemented by at least blocks 406 of FIG. 4. In some examples, the sensor interface circuitry 306 may be instantiated by hardware logic circuitry, which may be implemented by an ASIC, XPU, or the FPGA circuitry 700 of FIG. 7 configured and/or structured to perform operations corresponding to the machine-readable instructions. Additionally or alternatively, the sensor interface circuitry 306 may be instantiated by any other combination of hardware, software, and/or firmware. For example, the sensor interface circuitry 306 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

The example controller circuitry 178 is provided with the example flow restrictor control circuitry 308 to communicate with and/or control the flow restrictors 160, 162, 164, 166. That is, in some examples, the flow restrictor control circuitry 308 generates and/or provides command signals that control and/or adjust the flow restrictors 160, 162, 164, 166, thereby adjusting and/or controlling the downstream pressure of the coolant 110 (e.g., the inlet pressure of the coolant 110 provided to the nozzles 108). Further, in some examples, the flow restrictor control circuitry 308 receives signals from the flow restrictors 160, 162, 164, 166 indicating the state or position of the flow restrictors (e.g., how open or closed they are). In some examples, the flow restrictor control circuitry 308 is instantiated by programmable circuitry executing flow restrictor interface instructions and/or configured to perform operations such as those represented by the flowchart of FIG. 4.

In some examples, the controller circuitry 178 includes means for means for adjusting and/or controlling a flow restrictor. For example, the means for adjusting and/or controlling may be implemented by flow restrictor control circuitry 308. In some examples, the flow restrictor control circuitry 308 may be instantiated by programmable circuitry such as the example programmable circuitry 512 of FIG. 5. For instance, the flow restrictor control circuitry 308 may be instantiated by the example microprocessor 600 of FIG. 6 executing machine executable instructions such as those implemented by at least blocks 414, 416, 418 of FIG. 4. In some examples, the flow restrictor control circuitry 308 may be instantiated by hardware logic circuitry, which may be implemented by an ASIC, XPU, or the FPGA circuitry 700 of FIG. 7 configured and/or structured to perform operations corresponding to the machine-readable instructions. Additionally or alternatively, the flow restrictor control circuitry 308 may be instantiated by any other combination of hardware, software, and/or firmware. For example, the flow restrictor control circuitry 308 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

The example controller circuitry 178 is provided with the example set point comparison circuitry 310 to compare measured values (e.g., received from sensors via the sensor interface circuitry 306) to set point values (e.g., specified by a user via the user interface circuitry 302 and stored in the memory 314). In some examples, such comparisons are used to determine when changes need to be made to the operation of the jet impingement cooling system 100, 200. For instance, when a measured value deviates from an associated set point, the set point comparison circuitry 310 identifies this deviation and may cause the coolant control circuitry 304 and/or the flow restrictor control circuitry 308 to adjust equipment to result in the measured values being moved toward the associated set points. In some examples, the set point comparison circuitry 310 is instantiated by programmable circuitry executing set point comparison instructions and/or configured to perform operations such as those represented by the flowchart of FIG. 4.

In some examples, the controller circuitry 178 includes means for comparing measured data to corresponding set points (e.g., means for comparing a measured temperature to a temperature set point, etc.). For example, the means for determining may be implemented by set point comparison circuitry 310. In some examples, the set point comparison circuitry 310 may be instantiated by programmable circuitry such as the example programmable circuitry 512 of FIG. 5. For instance, the set point comparison circuitry 310 may be instantiated by the example microprocessor 600 of FIG. 6 executing machine executable instructions such as those implemented by at least blocks 408, 410, 416, 418 of FIG. 4. In some examples, the set point comparison circuitry 310 may be instantiated by hardware logic circuitry, which may be implemented by an ASIC, XPU, or the FPGA circuitry 700 of FIG. 7 configured and/or structured to perform operations corresponding to the machine-readable instructions. Additionally or alternatively, the set point comparison circuitry 310 may be instantiated by any other combination of hardware, software, and/or firmware. For example, the set point comparison circuitry 310 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

The example controller circuitry 178 is provided with the example nozzle flow determiner circuitry 312 to determine the flow parameters or characteristics of the coolant 110 as it passes through the nozzles 108. In some examples, such parameters include the inlet pressure of the coolant 110 provided to the nozzles 108 and/or the jet velocity output by the nozzles. As discussed above, these parameters are correlated such that the nozzle flow determiner circuitry 312 may only determine one of them directly. In some examples, the nozzle flow determiner circuitry 312 determines these parameters based on the die temperature set points for each zone 126, 128, 130, 132 of the IC packages 112, 114. Additionally or alternatively, the nozzle flow determiner circuitry 312 determines these parameters based on the comparison of the measured values relative to the set points provided by the set point comparison circuitry 310. In some examples, the flow characteristics of the coolant at the nozzles are not specifically determined. Instead, the flow characteristics are merely adjusted automatically (e.g., by adjusting the flow restrictors 160, 162, 164, 163) in response to deviations between the measured die temperatures and the set point die temperatures. That is, in some examples, the particular inlet pressure of the coolant 110 and/or the resulting jet velocity is not calculated in advance by the nozzle flow determiner circuitry 312, but simply arrived at by implementing a control loop. In some such examples, the nozzle flow determiner circuitry 312 may be omitted. In some examples, the nozzle flow determiner circuitry 312 is instantiated by programmable circuitry executing nozzle flow determiner instructions and/or configured to perform operations such as those represented by the flowchart of FIG. 4.

In some examples, the controller circuitry 178 includes means for determining nozzle flow characteristics (e.g., means for determining an inlet pressure of coolant to a nozzle, means for determining a jet velocity output from a nozzle, etc.). For example, the means for determining may be implemented by nozzle flow determiner circuitry 312. In some examples, the nozzle flow determiner circuitry 312 may be instantiated by programmable circuitry such as the example programmable circuitry 512 of FIG. 5. For instance, the nozzle flow determiner circuitry 312 may be instantiated by the example microprocessor 600 of FIG. 6 executing machine executable instructions such as those implemented by at least blocks 416, 418 of FIG. 4. In some examples, the nozzle flow determiner circuitry 312 may be instantiated by hardware logic circuitry, which may be implemented by an ASIC, XPU, or the FPGA circuitry 700 of FIG. 7 configured and/or structured to perform operations corresponding to the machine-readable instructions. Additionally or alternatively, the nozzle flow determiner circuitry 312 may be instantiated by any other combination of hardware, software, and/or firmware. For example, the nozzle flow determiner circuitry 312 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

While an example manner of implementing the controller circuitry 178 of FIGS. 1 and/or 2 is illustrated in FIG. 3, one or more of the elements, processes, and/or devices illustrated in FIG. 3 may be combined, divided, re-arranged, omitted, eliminated, and/or implemented in any other way. Further, the example user interface circuitry 302, the example coolant control circuitry 304, the example sensor interface circuitry 306, the example flow restrictor control circuitry 308, the example set point comparison circuitry 310, the example nozzle flow determiner circuitry 312, and the example memory 314, and/or, more generally, the example controller circuitry 178 of FIG. 3, may be implemented by hardware alone or by hardware in combination with software and/or firmware. Thus, for example, any of the example user interface circuitry 302, the example coolant control circuitry 304, the example sensor interface circuitry 306, the example flow restrictor control circuitry 308, the example set point comparison circuitry 310, the example nozzle flow determiner circuitry 312, and the example memory 314, and/or, more generally, the example controller circuitry 178, could be implemented by programmable circuitry in combination with machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example controller circuitry 178 of FIG. 3 may include one or more elements, processes, and/or devices in addition to, or instead of, those illustrated in FIG. 3, and/or may include more than one of any or all of the illustrated elements, processes and devices.

A flowchart representative of example machine-readable instructions, which may be executed by programmable circuitry to implement and/or instantiate the controller circuitry 178 of FIG. 3 and/or representative of example operations which may be performed by programmable circuitry to implement and/or instantiate the controller circuitry 178 of FIG. 3, are shown in FIG. 4. The machine-readable instructions may be one or more executable programs or portion(s) of one or more executable programs for execution by programmable circuitry such as the programmable circuitry 512 shown in the example processor platform 500 discussed below in connection with FIG. 5 and/or may be one or more function(s) or portion(s) of functions to be performed by the example programmable circuitry (e.g., an FPGA) discussed below in connection with FIGS. 6 and/or 7. In some examples, the machine-readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine-readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine-readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine-readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart illustrated in FIG. 4, many other methods of implementing the example controller circuitry 178 may alternatively be used. For example, the order of execution of the blocks of the flowchart may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine-readable instructions described herein may be stored in one or more of a compressed format, an encrypted format, a fragmented format, a compiled format, an executable format, a packaged format, etc. Machine-readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine-readable instructions may be fragmented and stored on one or more storage devices, disks and/or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine-readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions and/or the corresponding program(s) can be executed in whole or in part. Thus, machine-readable, computer readable and/or machine-readable media, as used herein, may include instructions and/or program(s) regardless of the particular format or state of the machine-readable instructions and/or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 4 may be implemented using executable instructions (e.g., computer readable and/or machine-readable instructions) stored on one or more non-transitory computer readable and/or machine-readable media. As used herein, the terms non-transitory computer readable medium, non-transitory computer readable storage medium, non-transitory machine-readable medium, and/or non-transitory machine-readable storage medium are expressly defined to include any type of computer readable storage device and/or storage disk and to exclude propagating signals and to exclude transmission media. Examples of such non-transitory computer readable medium, non-transitory computer readable storage medium, non-transitory machine-readable medium, and/or non-transitory machine-readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine-readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine-readable instructions, etc., and/or manufactured to execute computer-readable instructions, machine-readable instructions, etc.

FIG. 4 is a flowchart representative of example machine-readable instructions and/or example operations 400 that may be executed, instantiated, and/or performed by programmable circuitry to dynamically and independently control the die temperature of different zones in an IC package (e.g., the IC packages 112, 114 of FIGS. 1 and/or 2). The example machine-readable instructions and/or the example operations 400 of FIG. 4 begin at block 402, where the example user interface circuitry 302 obtains die temperature set points for different zones (e.g., the zones 126, 128, 130, 132) of an IC package (e.g., the IC packages 112, 114). At block 404, the example coolant control circuitry 304 adjusts an input temperature of the coolant (e.g., the coolant 110) based on the die temperature set points. In some examples, the input temperature of the coolant 110 corresponds to the temperature of the coolant 110 as output by the heater 154, as shown in FIG. 1. In other examples, the input temperature of the coolant 110 corresponds to the temperature after mixing coolant from the cold and heated lines 202, 204, as shown in FIG. 2.

At block 406, the example sensor interface circuitry 306 obtains the current temperature (e.g., a measured temperature) of the different zones 126, 128, 130, 132. That is, in some examples, the sensor interface circuitry 306 obtains temperature data from the temperature sensors 180. At block 408, the example set point comparison circuitry 310 compares the current (e.g., measured) temperature of each zone 126, 128, 130, 132 to the corresponding die temperature set point. At block 410, the example set point comparison circuitry 310 determines whether to adjust the die temperature of a given zone. In some examples, this determination is made based on whether the current (e.g., measured) temperature of the zones deviates from the corresponding die temperature set point. If the die temperature of a given zone is to be adjusted, control advances to block 412. At block 412, the example nozzle flow determiner circuitry 312 determines a velocity of a jet stream from nozzle(s) 108 associated with the given zone to achieve the temperature adjustment. At block 414, the example flow restrictor control circuitry 308 adjusts a flow restrictor (e.g., the flow restrictors 160, 162, 164, 166) to change an inlet pressure of the coolant 110 provided to the nozzle(s) 108 to produce a jet stream at the determined velocity. Thereafter, control advances to block 416. In some examples, the velocity of the jet stream is not directly determined. In some such examples, block 412 is omitted and the example flow restrictor control circuitry 308 adjusts (at block 414) the relevant flow restrictor 160, 162, 164, 166 to change the inlet pressure in a manner that will adjust the jet velocity so as to reduce a deviation between the current (measured) temperature and the die temperature set point.

Returning to block 410, if the example set point comparison circuitry 310 determines not to adjust the die temperature of a given zone, control advances directly to block 416. At block 416, the example controller circuitry 178 (e.g., via the flow restrictor control circuitry 308, the set point comparison circuitry 310, and/or the nozzle flow determiner circuitry 312) determines whether there is another zone to consider. If so, control returns to block 410. Otherwise, control advances to block 418, where the example controller circuitry 178 (e.g., via the flow restrictor control circuitry 308, the set point comparison circuitry 310, and/or the nozzle flow determiner circuitry 312) determines whether to continue monitoring the system. If so, control returns to block 406. Otherwise, the example operations 400 end.

FIG. 5 is a block diagram of an example programmable circuitry platform 500 structured to execute and/or instantiate the example machine-readable instructions and/or the example operations of FIG. 4 to implement the controller circuitry 178 of FIG. 3. The programmable circuitry platform 500 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, or any other type of computing and/or electronic device.

The programmable circuitry platform 500 of the illustrated example includes programmable circuitry 512. The programmable circuitry 512 of the illustrated example is hardware. For example, the programmable circuitry 512 can be implemented by one or more integrated circuits, logic circuits, FPGAs, microprocessors, CPUs, GPUs, DSPs, and/or microcontrollers from any desired family or manufacturer. The programmable circuitry 512 may be implemented by one or more semiconductor based (e.g., silicon based) devices. In this example, the programmable circuitry 512 implements the example user interface circuitry 302, the example coolant control circuitry 304, the example sensor interface circuitry 306, the example flow restrictor control circuitry 308, the example set point comparison circuitry 310, and the example nozzle flow determiner circuitry 312.

The programmable circuitry 512 of the illustrated example includes a local memory 513 (e.g., a cache, registers, etc.). The programmable circuitry 512 of the illustrated example is in communication with main memory 514, 516, which includes a volatile memory 514 and a non-volatile memory 516, by a bus 518. The volatile memory 514 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 516 may be implemented by flash memory and/or any other desired type of memory device. Access to the main memory 514, 516 of the illustrated example is controlled by a memory controller 517. In some examples, the memory controller 517 may be implemented by one or more integrated circuits, logic circuits, microcontrollers from any desired family or manufacturer, or any other type of circuitry to manage the flow of data going to and from the main memory 514, 516.

The programmable circuitry platform 500 of the illustrated example also includes interface circuitry 520. The interface circuitry 520 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 522 are connected to the interface circuitry 520. The input device(s) 522 permit(s) a user (e.g., a human user, a machine user, etc.) to enter data and/or commands into the programmable circuitry 512. The input device(s) 522 can be implemented by, for example, an audio sensor, a microphone, a camera (still or video), a keyboard, a button, a mouse, a touchscreen, a trackpad, a trackball, an isopoint device, and/or a voice recognition system.

One or more output devices 524 are also connected to the interface circuitry 520 of the illustrated example. The output device(s) 524 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 520 of the illustrated example, thus, typically includes a graphics driver card, a graphics driver chip, and/or graphics processor circuitry such as a GPU.

The interface circuitry 520 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 526. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 500 of the illustrated example also includes one or more mass storage discs or devices 528 to store firmware, software, and/or data. Examples of such mass storage discs or devices 528 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine-readable instructions 532, which may be implemented by the machine-readable instructions of FIG. 4, may be stored in the mass storage device 528, in the volatile memory 514, in the non-volatile memory 516, and/or on at least one non-transitory computer readable storage medium such as a CD or DVD which may be removable.

FIG. 6 is a block diagram of an example implementation of the programmable circuitry 512 of FIG. 5. In this example, the programmable circuitry 512 of FIG. 5 is implemented by a microprocessor 600. For example, the microprocessor 600 may be a general-purpose microprocessor (e.g., general-purpose microprocessor circuitry). The microprocessor 600 executes some or all of the machine-readable instructions of the flowchart of FIG. 4 to effectively instantiate the circuitry of FIG. 3 as logic circuits to perform operations corresponding to those machine-readable instructions. In some such examples, the circuitry of FIG. 3 is instantiated by the hardware circuits of the microprocessor 600 in combination with the machine-readable instructions. For example, the microprocessor 600 may be implemented by multi-core hardware circuitry such as a CPU, a DSP, a GPU, an XPU, etc. Although it may include any number of example cores 602 (e.g., 1 core), the microprocessor 600 of this example is a multi-core semiconductor device including N cores. The cores 602 of the microprocessor 600 may operate independently or may cooperate to execute machine-readable instructions. For example, machine code corresponding to a firmware program, an embedded software program, or a software program may be executed by one of the cores 602 or may be executed by multiple ones of the cores 602 at the same or different times. In some examples, the machine code corresponding to the firmware program, the embedded software program, or the software program is split into threads and executed in parallel by two or more of the cores 602. The software program may correspond to a portion or all of the machine-readable instructions and/or operations represented by the flowchart of FIG. 4.

The cores 602 may communicate by a first example bus 604. In some examples, the first bus 604 may be implemented by a communication bus to effectuate communication associated with one(s) of the cores 602. For example, the first bus 604 may be implemented by at least one of an Inter-Integrated Circuit (I2C) bus, a Serial Peripheral Interface (SPI) bus, a PCI bus, or a PCIe bus. Additionally or alternatively, the first bus 604 may be implemented by any other type of computing or electrical bus. The cores 602 may obtain data, instructions, and/or signals from one or more external devices by example interface circuitry 606. The cores 602 may output data, instructions, and/or signals to the one or more external devices by the interface circuitry 606. Although the cores 602 of this example include example local memory 620 (e.g., Level 1 (L1) cache that may be split into an L1 data cache and an L1 instruction cache), the microprocessor 600 also includes example shared memory 610 that may be shared by the cores (e.g., Level 2 (L2 cache)) for high-speed access to data and/or instructions. Data and/or instructions may be transferred (e.g., shared) by writing to and/or reading from the shared memory 610. The local memory 620 of each of the cores 602 and the shared memory 610 may be part of a hierarchy of storage devices including multiple levels of cache memory and the main memory (e.g., the main memory 514, 516 of FIG. 5). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 602 may be referred to as a CPU, DSP, GPU, etc., or any other type of hardware circuitry. Each core 602 includes control unit circuitry 614, arithmetic and logic (AL) circuitry (sometimes referred to as an ALU) 616, a plurality of registers 618, the local memory 620, and a second example bus 622. Other structures may be present. For example, each core 602 may include vector unit circuitry, single instruction multiple data (SIMD) unit circuitry, load/store unit (LSU) circuitry, branch/jump unit circuitry, floating-point unit (FPU) circuitry, etc. The control unit circuitry 614 includes semiconductor-based circuits structured to control (e.g., coordinate) data movement within the corresponding core 602. The AL circuitry 616 includes semiconductor-based circuits structured to perform one or more mathematic and/or logic operations on the data within the corresponding core 602. The AL circuitry 616 of some examples performs integer based operations. In other examples, the AL circuitry 616 also performs floating-point operations. In yet other examples, the AL circuitry 616 may include first AL circuitry that performs integer-based operations and second AL circuitry that performs floating-point operations. In some examples, the AL circuitry 616 may be referred to as an Arithmetic Logic Unit (ALU).

The registers 618 are semiconductor-based structures to store data and/or instructions such as results of one or more of the operations performed by the AL circuitry 616 of the corresponding core 602. For example, the registers 618 may include vector register(s), SIMD register(s), general-purpose register(s), flag register(s), segment register(s), machine-specific register(s), instruction pointer register(s), control register(s), debug register(s), memory management register(s), machine check register(s), etc. The registers 618 may be arranged in a bank as shown in FIG. 6. Alternatively, the registers 618 may be organized in any other arrangement, format, or structure, such as by being distributed throughout the core 602 to shorten access time. The second bus 622 may be implemented by at least one of an I2C bus, a SPI bus, a PCI bus, or a PCIe bus.

Each core 602 and/or, more generally, the microprocessor 600 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 600 is a semiconductor device fabricated to include many transistors interconnected to implement the structures described above in one or more integrated circuits (ICs) contained in one or more packages.

The microprocessor 600 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 600, in the same chip package as the microprocessor 600 and/or in one or more separate packages from the microprocessor 600.

FIG. 7 is a block diagram of another example implementation of the programmable circuitry 512 of FIG. 5. In this example, the programmable circuitry 512 is implemented by FPGA circuitry 700. For example, the FPGA circuitry 700 may be implemented by an FPGA. The FPGA circuitry 700 can be used, for example, to perform operations that could otherwise be performed by the example microprocessor 600 of FIG. 6 executing corresponding machine-readable instructions. However, once configured, the FPGA circuitry 700 instantiates the operations and/or functions corresponding to the machine-readable instructions in hardware and, thus, can often execute the operations/functions faster than they could be performed by a general-purpose microprocessor executing the corresponding software.

More specifically, in contrast to the microprocessor 600 of FIG. 6 described above (which is a general purpose device that may be programmed to execute some or all of the machine-readable instructions represented by the flowchart of FIG. 4 but whose interconnections and logic circuitry are fixed once fabricated), the FPGA circuitry 700 of the example of FIG. 7 includes interconnections and logic circuitry that may be configured, structured, programmed, and/or interconnected in different ways after fabrication to instantiate, for example, some or all of the operations/functions corresponding to the machine-readable instructions represented by the flowchart of FIG. 4. In particular, the FPGA circuitry 700 may be thought of as an array of logic gates, interconnections, and switches. The switches can be programmed to change how the logic gates are interconnected by the interconnections, effectively forming one or more dedicated logic circuits (unless and until the FPGA circuitry 700 is reprogrammed). The configured logic circuits enable the logic gates to cooperate in different ways to perform different operations on data received by input circuitry. Those operations may correspond to some or all of the instructions (e.g., the software and/or firmware) represented by the flowchart of FIG. 4. As such, the FPGA circuitry 700 may be configured and/or structured to effectively instantiate some or all of the operations/functions corresponding to the machine-readable instructions of the flowchart of FIG. 4 as dedicated logic circuits to perform the operations/functions corresponding to those software instructions in a dedicated manner analogous to an ASIC. Therefore, the FPGA circuitry 700 may perform the operations/functions corresponding to the some or all of the machine-readable instructions of FIG. 4 faster than the general-purpose microprocessor can execute the same.

In the example of FIG. 7, the FPGA circuitry 700 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 700 of FIG. 7 may access and/or load the binary file to cause the FPGA circuitry 700 of FIG. 7 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 700 of FIG. 7 to cause configuration and/or structuring of the FPGA circuitry 700 of FIG. 7, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 700 of FIG. 7 may access and/or load the binary file to cause the FPGA circuitry 700 of FIG. 7 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 700 of FIG. 7 to cause configuration and/or structuring of the FPGA circuitry 700 of FIG. 7, or portion(s) thereof.

The FPGA circuitry 700 of FIG. 7, includes example input/output (I/O) circuitry 702 to obtain and/or output data to/from example configuration circuitry 704 and/or external hardware 706. For example, the configuration circuitry 704 may be implemented by interface circuitry that may obtain a binary file, which may be implemented by a bit stream, data, and/or machine-readable instructions, to configure the FPGA circuitry 700, or portion(s) thereof. In some such examples, the configuration circuitry 704 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 706 may be implemented by external hardware circuitry. For example, the external hardware 706 may be implemented by the microprocessor 600 of FIG. 6.

The FPGA circuitry 700 also includes an array of example logic gate circuitry 708, a plurality of example configurable interconnections 710, and example storage circuitry 712. The logic gate circuitry 708 and the configurable interconnections 710 are configurable to instantiate one or more operations/functions that may correspond to at least some of the machine-readable instructions of FIG. 4 and/or other desired operations. The logic gate circuitry 708 shown in FIG. 7 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 708 to enable configuration of the electrical structures and/or the logic gates to form circuits to perform desired operations/functions. The logic gate circuitry 708 may include other electrical structures such as look-up tables (LUTs), registers (e.g., flip-flops or latches), multiplexers, etc.

The configurable interconnections 710 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 708 to program desired logic circuits.

The storage circuitry 712 of the illustrated example is structured to store result(s) of the one or more of the operations performed by corresponding logic gates. The storage circuitry 712 may be implemented by registers or the like. In the illustrated example, the storage circuitry 712 is distributed amongst the logic gate circuitry 708 to facilitate access and increase execution speed.

The example FPGA circuitry 700 of FIG. 7 also includes example dedicated operations circuitry 714. In this example, the dedicated operations circuitry 714 includes special purpose circuitry 716 that may be invoked to implement commonly used functions to avoid the need to program those functions in the field. Examples of such special purpose circuitry 716 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 700 may also include example general purpose programmable circuitry 718 such as an example CPU 720 and/or an example DSP 722. Other general purpose programmable circuitry 718 may additionally or alternatively be present such as a GPU, an XPU, etc., that can be programmed to perform other operations.

Although FIGS. 6 and 7 illustrate two example implementations of the programmable circuitry 512 of FIG. 5, many other approaches are contemplated. For example, FPGA circuitry may include an on-board CPU, such as one or more of the example CPU 720 of FIG. 6. Therefore, the programmable circuitry 512 of FIG. 5 may additionally be implemented by combining at least the example microprocessor 600 of FIG. 6 and the example FPGA circuitry 700 of FIG. 7. In some such hybrid examples, one or more cores 602 of FIG. 6 may execute a first portion of the machine-readable instructions represented by the flowchart of FIG. 4 to perform first operation(s)/function(s), the FPGA circuitry 700 of FIG. 7 may be configured and/or structured to perform second operation(s)/function(s) corresponding to a second portion of the machine-readable instructions represented by the flowchart of FIG. 4, and/or an ASIC may be configured and/or structured to perform third operation(s)/function(s) corresponding to a third portion of the machine-readable instructions represented by the flowchart of FIG. 4.

It should be understood that some or all of the circuitry of FIG. 3 may, thus, be instantiated at the same or different times. For example, same and/or different portion(s) of the microprocessor 600 of FIG. 6 may be programmed to execute portion(s) of machine-readable instructions at the same and/or different times. In some examples, same and/or different portion(s) of the FPGA circuitry 700 of FIG. 7 may be configured and/or structured to perform operations/functions corresponding to portion(s) of machine-readable instructions at the same and/or different times.

In some examples, some or all of the circuitry of FIG. 3 may be instantiated, for example, in one or more threads executing concurrently and/or in series. For example, the microprocessor 600 of FIG. 6 may execute machine-readable instructions in one or more threads executing concurrently and/or in series. In some examples, the FPGA circuitry 700 of FIG. 7 may be configured and/or structured to carry out operations/functions concurrently and/or in series. Moreover, in some examples, some or all of the circuitry of FIG. 3 may be implemented within one or more virtual machines and/or containers executing on the microprocessor 600 of FIG. 6.

In some examples, the programmable circuitry 512 of FIG. 5 may be in one or more packages. For example, the microprocessor 600 of FIG. 6 and/or the FPGA circuitry 700 of FIG. 7 may be in one or more packages. In some examples, an XPU may be implemented by the programmable circuitry 512 of FIG. 5, which may be in one or more packages. For example, the XPU may include a CPU (e.g., the microprocessor 600 of FIG. 6, the CPU 720 of FIG. 7, etc.) in one package, a DSP (e.g., the DSP 722 of FIG. 7) in another package, a GPU in yet another package, and an FPGA (e.g., the FPGA circuitry 700 of FIG. 7) in still yet another package.

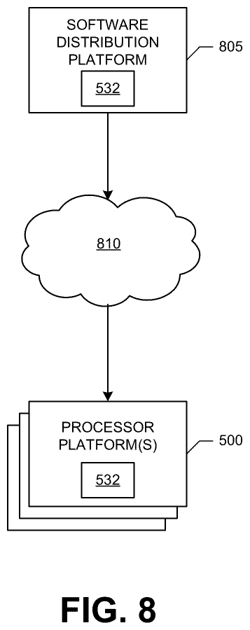

A block diagram illustrating an example software distribution platform 805 to distribute software such as the example machine-readable instructions 532 of FIG. 5 to other hardware devices (e.g., hardware devices owned and/or operated by third parties from the owner and/or operator of the software distribution platform) is illustrated in FIG. 8. The example software distribution platform 805 may be implemented by any computer server, data facility, cloud service, etc., capable of storing and transmitting software to other computing devices. The third parties may be customers of the entity owning and/or operating the software distribution platform 805. For example, the entity that owns and/or operates the software distribution platform 805 may be a developer, a seller, and/or a licensor of software such as the example machine-readable instructions 532 of FIG. 5. The third parties may be consumers, users, retailers, OEMs, etc., who purchase and/or license the software for use and/or re-sale and/or sub-licensing. In the illustrated example, the software distribution platform 805 includes one or more servers and one or more storage devices. The storage devices store the machine-readable instructions 532, which may correspond to the example machine-readable instructions of FIG. 4, as described above. The one or more servers of the example software distribution platform 805 are in communication with an example network 810, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine-readable instructions 532 from the software distribution platform 805. For example, the software, which may correspond to the example machine-readable instructions of FIG. 4, may be downloaded to the example programmable circuitry platform 500, which is to execute the machine-readable instructions 532 to implement the controller circuitry 178. In some examples, one or more servers of the software distribution platform 805 periodically offer, transmit, and/or force updates to the software (e.g., the example machine-readable instructions 532 of FIG. 5) to ensure improvements, patches, updates, etc., are distributed and applied to the software at the end user devices. Although referred to as software above, the distributed “software” could alternatively be firmware.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable the dynamic control of die temperature of different zones of an IC package independent of other zones in a reliable and efficient manner by adjusting the inlet pressure of coolant provided to nozzles that provide jet streams impinging on the different zones. Examples disclosed herein save on cost, space, and complexity relative to known die temperature control systems inasmuch as fewer components are needed with fewer constraints on the location (e.g., distance apart) of such components. Furthermore, examples disclosed herein provide faster response times than is possible with known systems. Further still, examples disclosed herein are not subject to concerns of cross-talk between different jet streams. Moreover, examples disclosed herein are suitable for either one-phase or two-phase jet impingement cooling systems.

Further examples and combinations thereof include the following:

Example 1 includes a system comprising a first nozzle to direct a first portion of impingement fluid towards an integrated circuit package, a second nozzle to direct a second portion of the impingement fluid towards the integrated circuit package, a first flow restrictor to control a first pressure of the first portion of the impingement fluid provided to the first nozzle, and a second flow restrictor to control a second pressure of the second portion of the impingement fluid provided to the second nozzle.

Example 2 includes the system of example 1, wherein the second pressure is to be controlled independent of the first pressure.

Example 3 includes the system of any one of examples 1 or 2, wherein an entirety of the first portion of the impingement fluid provided to the first nozzle is to flow through the first flow restrictor.

Example 4 includes the system of any one of examples 1-3, further including, a first pressure sensor to measure the first pressure, and a second pressure sensor to measure the second pressure, and a third pressure sensor to measure a third pressure within a chamber that is to contain the integrated circuit package.

Example 5 includes the system of any one of examples 1-4, wherein the first and second portions of the impingement fluid are to have a same temperature.

Example 6 includes the system of example 5, including a heater to increase a temperature of the impingement fluid provided from a fluid line upstream of the first and second flow restrictors.

Example 7 includes the system of example 6, including a valve to mix a first fluid with a second fluid to produce the impingement fluid, the valve upstream of the common fluid line, the first fluid corresponding to an output of the heater, the second fluid cooler than the first fluid.

Example 8 includes the system of example 7, wherein the valve is a first valve, the system including a second valve to mix the first fluid with the second fluid to produce a third fluid, the third fluid to be provided to a third nozzle that is to direct the third fluid to a second integrated circuit package, the third fluid having a different temperature from the impingement fluid.

Example 9 includes the system of any one of examples 1-8, wherein at least some of the first portion of the impingement fluid is to change from a liquid phase to a vapor phase when the impingement fluid enters a chamber containing the integrated circuit package.

Example 10 includes the system of any one of examples 1-9, wherein the first flow restrictor is at least one of a proportional valve, a solenoid valve, a butterfly valve, or a needle valve.

Example 11 includes the system of any one of examples 1-10, wherein the first flow restrictor is upstream of the first nozzle by a first distance, and the second flow restrictor is upstream of the second nozzle by a second distance, the second distance different from the first distance.

Example 12 includes the system of any one of examples 1-11, wherein the first nozzle is to direct the first portion of impingement fluid towards a first zone of the integrated circuit package, the first zone has a first die associated with a first die height, the second nozzle is to direct the second portion of the impingement fluid towards a second zone of the integrated circuit package, and the second zone has a second die associated with a second die height different from the first die height.

Example 13 includes the system of any one of examples 1-12, wherein the first nozzle is to direct the first portion of impingement fluid towards a first die of the integrated circuit package, and the second nozzle is to direct the second portion of impingement fluid towards a second die of the integrated circuit package.

Example 14 includes an apparatus comprising interface circuitry, machine-readable instructions, and at least one processor circuit to be programmed by the instructions to cause adjustment of a first flow restrictor to change a first inlet pressure of a coolant to be provided to a first nozzle downstream of the first flow restrictor, the first nozzle to direct the coolant towards a first zone of an integrated circuit package, and cause adjustment of a second flow restrictor to change a second inlet pressure of the coolant to be provided to a second nozzle downstream of the second flow restrictor, the second nozzle to direct the coolant towards a second zone of the integrated circuit package.

Example 15 includes the apparatus of example 14, wherein the adjustment of the first flow restrictor is independent of the adjustment of the second flow restrictor.

Example 16 includes the apparatus of any one of examples 14 or 15, wherein one or more of the at least one processor circuit is to determine a first temperature of the first zone of the integrated circuit package based on sensor data from a first temperature sensor, the first flow restrictor to be adjusted based on the first temperature.

Example 17 includes the apparatus of example 16, wherein one or more of the at least one processor circuit is to cause adjustment of the first flow restrictor based on a comparison of the first temperature to a first set point.

Example 18 includes the apparatus of example 17, wherein one or more of the at least one processor circuit is to determine a second temperature of the second zone of the integrated circuit package, and cause adjustment of the second flow restrictor based on a comparison of the second temperature to a second set point, the second set point different from the first set point.

Example 19 includes a non-transitory machine-readable storage medium comprising instructions to cause at least one processor circuit to at least cause adjustment of a first flow restrictor to change a first inlet pressure of a coolant to be provided to a first nozzle downstream of the first flow restrictor, the first nozzle to direct the coolant towards a first zone of an integrated circuit package, and cause adjustment of a second flow restrictor to change a second inlet pressure of the coolant to be provided to a second nozzle downstream of the second flow restrictor, the second nozzle to direct the coolant towards a second zone of the integrated circuit package.

Example 20 includes the non-transitory machine-readable storage medium of example 19, wherein the adjustment of the first flow restrictor is independent of the adjustment of the second flow restrictor.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A system comprising:
a first nozzle to direct a first portion of impingement fluid towards an integrated circuit package;
a second nozzle to direct a second portion of the impingement fluid towards the integrated circuit package;
a first flow restrictor to control a first pressure of the first portion of the impingement fluid provided to the first nozzle; and
a second flow restrictor to control a second pressure of the second portion of the impingement fluid provided to the second nozzle.

2. The system of claim 1, wherein the second pressure is to be controlled independent of the first pressure.

3. The system of claim 1, wherein an entirety of the first portion of the impingement fluid provided to the first nozzle is to flow through the first flow restrictor.

4. The system of claim 1, further including;
a first pressure sensor to measure the first pressure; and
a second pressure sensor to measure the second pressure; and
a third pressure sensor to measure a third pressure within a chamber that is to contain the integrated circuit package.

5. The system of claim 1, wherein the first and second portions of the impingement fluid are to have a same temperature.

6. The system of claim 5, including a heater to increase a temperature of the impingement fluid provided from a fluid line upstream of the first and second flow restrictors.

7. The system of claim 6, including a valve to mix a first fluid with a second fluid to produce the impingement fluid, the valve upstream of the common fluid line, the first fluid corresponding to an output of the heater, the second fluid cooler than the first fluid.

8. The system of claim 7, wherein the valve is a first valve, the system including a second valve to mix the first fluid with the second fluid to produce a third fluid, the third fluid to be provided to a third nozzle that is to direct the third fluid to a second integrated circuit package, the third fluid having a different temperature from the impingement fluid.

9. The system of claim 1, wherein at least some of the first portion of the impingement fluid is to change from a liquid phase to a vapor phase when the impingement fluid enters a chamber containing the integrated circuit package.

10. The system of claim 1, wherein the first flow restrictor is at least one of a proportional valve, a solenoid valve, a butterfly valve, or a needle valve.

11. The system of claim 1, wherein the first flow restrictor is upstream of the first nozzle by a first distance, and the second flow restrictor is upstream of the second nozzle by a second distance, the second distance different from the first distance.

12. The system of claim 1, wherein the first nozzle is to direct the first portion of impingement fluid towards a first zone of the integrated circuit package, the first zone has a first die associated with a first die height, the second nozzle is to direct the second portion of the impingement fluid towards a second zone of the integrated circuit package, and the second zone has a second die associated with a second die height different from the first die height.

13. The system of claim 1, wherein the first nozzle is to direct the first portion of impingement fluid towards a first die of the integrated circuit package, and the second nozzle is to direct the second portion of impingement fluid towards a second die of the integrated circuit package.

14. An apparatus comprising:
interface circuitry;
machine-readable instructions; and
at least one processor circuit to be programmed by the instructions to:
cause adjustment of a first flow restrictor to change a first inlet pressure of a coolant to be provided to a first nozzle downstream of the first flow restrictor, the first nozzle to direct the coolant towards a first zone of an integrated circuit package; and
cause adjustment of a second flow restrictor to change a second inlet pressure of the coolant to be provided to a second nozzle downstream of the second flow restrictor, the second nozzle to direct the coolant towards a second zone of the integrated circuit package.

15. The apparatus of claim 14, wherein the adjustment of the first flow restrictor is independent of the adjustment of the second flow restrictor.

16. The apparatus of claim 14, wherein one or more of the at least one processor circuit is to determine a first temperature of the first zone of the integrated circuit package based on sensor data from a first temperature sensor, the first flow restrictor to be adjusted based on the first temperature.

17. The apparatus of claim 16, wherein one or more of the at least one processor circuit is to cause adjustment of the first flow restrictor based on a comparison of the first temperature to a first set point.

18. The apparatus of claim 17, wherein one or more of the at least one processor circuit is to:
determine a second temperature of the second zone of the integrated circuit package; and
cause adjustment of the second flow restrictor based on a comparison of the second temperature to a second set point, the second set point different from the first set point.

19. A non-transitory machine-readable storage medium comprising instructions to cause at least one processor circuit to at least:
cause adjustment of a first flow restrictor to change a first inlet pressure of a coolant to be provided to a first nozzle downstream of the first flow restrictor, the first nozzle to direct the coolant towards a first zone of an integrated circuit package; and
cause adjustment of a second flow restrictor to change a second inlet pressure of the coolant to be provided to a second nozzle downstream of the second flow restrictor, the second nozzle to direct the coolant towards a second zone of the integrated circuit package.

20. The non-transitory machine-readable storage medium of claim 19, wherein the adjustment of the first flow restrictor is independent of the adjustment of the second flow restrictor.
